(19) United States
(12) Patent Application Publication
(10) Pub. No.: US 2024/0348007 A1
(43) Pub. Date: Oct. 17, 2024

(54) FIBER LASER SYSTEM MONITOR USING ONE OR MORE PHOTODIODES

(71) Applicant: nLIGHT, Inc., Camas, WA (US)

(72) Inventor: Kenneth V. ALMONTE, Camas, WA (US)

(21) Appl. No.: 18/628,180

(22) Filed: Apr. 5, 2024

Related U.S. Application Data
(60) Provisional application No. 63/458,515, filed on Apr. 11, 2023.

(51) Int. Cl. H01S 5/026; H01S 5/02251

(52) U.S. Cl. CPC H01S 5/0264; H01S 5/02251

(57) ABSTRACT

A fiber laser system monitor includes a fiber laser adapted to generate fiber laser light, a first light emitter adapted to generate first emitted light, a photodiode adapted to receive the first emitted light and the fiber laser light and to generate a received light signal responsive thereto, and a controller connected to the fiber laser, the first light emitter, and the photodiode. The controller receives the received light signal. The controller is configured to determine an acceptable operation for the fiber laser, the first light emitter, and the photodiode by comparing the received light signal with a predetermined maximum threshold and with a predetermined minimum threshold.

### CROSS-REFERENCE TO RELATED APPLICATION(S)

This patent application relies on and claims priority to U.S. Patent Application No. 63/458,515, filed on Apr. 11, 2023, the entire content of which is incorporated herein by reference.

### FIELD OF THE INVENTION

The present invention concerns a construction an apparatus and method for monitoring fiber lasers in a fiber laser system using one or more photodiodes.

### DESCRIPTION OF THE RELATED ART

Photodiodes operate by converting detected light, typically of a certain wavelength or within a certain range of wavelengths, into an output signal that is proportional to the intensity of the detected light.

As should be apparent to those skilled in the art, it is commonplace to rely on photodiodes to monitor the amount of light generated by a fiber laser under specific operating conditions. In particular, it is known to employ photodiodes to detect if too much light is being generated by a fiber laser, because the generation of too much light by the fiber laser may indicate a problem with the fiber laser.

Specifically, if the photodiodes detect too much light being generated by the fiber laser, the excessive generation of light by the fiber laser may indicate potential damage to the fiber laser or potential damage to other components of the fiber laser system.

One difficulty with prior art detection systems and methods is that a failure of a fiber laser may not be detected soon enough. This can result in damage to the fiber laser and its associated components.

Another problem with prior art photodiode detection systems arises if the photodiode is faulty, becomes blocked, or becomes disconnected. These conditions of the photodiode are not monitored in prior art systems, because prior art systems merely compare the output of the photodiode against a maximum threshold. Therefore, if the photodiode generates an output signal with a magnitude that is less than the threshold or if the photodiode fails to generate any signal, potential failure conditions of the fiber laser may not be detected.

In view of the foregoing, there exists a need for improved systems and methods for monitoring the operation of a fiber laser to enhance the operation and safety of the fiber laser.

### SUMMARY OF THE INVENTION

In one or more non-limiting examples, the present invention provides a fiber laser system monitor that includes a fiber laser adapted to generate fiber laser light, a first light emitter adapted to generate first emitted light, a photodiode adapted to receive the first emitted light and the fiber laser light and to generate a received light signal responsive thereto, and a controller connected to the fiber laser, the first light emitter, and the photodiode. The controller receives the received light signal. The controller is configured to determine an acceptable operation for the fiber laser, the first light emitter, and the photodiode by comparing the received light signal with a predetermined maximum threshold and with a predetermined minimum threshold.

In one contemplated example of the fiber laser system monitor, the fiber laser is separated from the photodiode by a first predetermined distance.

In another non-limiting example, the fiber laser system monitor includes a substrate, with the first light emitter and the photodiode being disposed on the substrate.

Still further, it is contemplated that, in one example of the fiber laser system monitor of the present invention, the first light emitter is separated from the photodiode by a second predetermined distance.

In one contemplated example, the first light emitter is a light emitting diode.

It is contemplated that the photodiode may detect light within the infrared portion of the electromagnetic spectrum, in another non-limiting example.

In addition, the fiber laser system monitor described herein may be configured so that the controller includes a processor adapted to execute software to determine the acceptable operation for the fiber laser, the first light emitter, and the photodiode by comparing the received light signal with the predetermined maximum threshold and with the predetermined minimum threshold.

In an example of the fiber laser system monitor described herein, if the received light signal exceeds the predetermined maximum threshold, the received light signal is determined to be aberrant. Similarly, if the received light signal is below the predetermined minimum threshold, the received light signal is aberrant. The controller prohibits operation of the fiber laser when the received light signal is aberrant.

In a further non-limiting example, the fiber laser system monitor may include a reflector. If so, the reflector may be positioned between the substrate and the fiber laser. Here, the reflector reflects the first light emitter to the photodiode. In addition, the reflector is at least partially transmissive, permitting the fiber laser light to pass therethrough and be received by the photodiode.

The fiber laser system monitor also may be constructed to include a second light emitter adapted to generate second emitted light. If so, the received light signal generated by the photodiode also is contemplated to be responsive to the second emitted light.

Where the fiber laser system includes a second light emitter, it is contemplated that the fiber laser system monitor may include a substrate. The first light emitter, the second light emitter, and the photodiode may be disposed on the substrate.

In another example discussed herein, components of the fiber laser system monitor are arranged so that the first light emitter is separated from the photodiode by a third predetermined distance and the second light emitter is separated from the photodiode by a fourth predetermined distance.

It is contemplated that the photodiode may be disposed between the first light emitter and the second light emitter.

In other contemplated examples, the first light emitter is a light emitting diode and the second light emitter is a light emitting diode.

As discussed herein, without limiting the present invention, the first emitted light and the second emitted light are contemplated to be within the infrared portion of the electromagnetic spectrum. The first emitted light and the second emitted light also may be within other parts of the electromagnetic spectrum aside from (and/or in addition to) the infrared portion of the electromagnetic spectrum.

It is contemplated that one example of the fiber laser system monitor may include a housing encompassing the fiber laser, the first light emitter, and the photodiode. If so, an interior surface of the housing is contemplated to include a reflective surface.

The fiber laser monitor discussed herein also may include a housing that encompasses the fiber laser, the first light emitter, and the photodiode. If so, an interior surface of the housing may include a reflective surface in one non-limiting example.

In another non-limiting example, the fiber laser monitor is contemplated to include a first substrate and a second substrate. Here, the first light emitter and the second light emitter are contemplated to be disposed on the first substrate, the photodiode is contemplated to be disposed on the second substrate, and the fiber laser is contemplated to be disposed between the first substrate and the second substrate.

It is further contemplated that the fiber laser monitor may have a housing encompassing the fiber laser, the first light emitter, and the photodiode. As before, an interior surface of the housing may include a reflective surface.

Still further advantages and features of the present invention will be made apparent by the discussion presented hereinbelow.

### BRIEF DESCRIPTION OF THE DRAWINGS

The present invention will now be described in connection with the drawings appended hereto, in which:

FIG. 1 is a graphical, side view of a fiber laser system monitor according to a first embodiment of the present invention;

FIG. 2 is a graphical, top view of the fiber laser system monitor illustrated in FIG. 1;

FIG. 3 is a graphical, side view of a fiber laser system monitor according to a second embodiment of the present invention;

FIG. 4 is a graphical, side view of a fiber laser system monitor according to a third embodiment of the present invention; and

FIG. 5 is a graph providing a representative output for the fiber laser system monitor according to the present invention.

### DETAILED DESCRIPTION OF EMBODIMENT(S) OF THE INVENTION

The present invention will now be described in connection with several embodiments. The present invention should not be understood to be limited solely to the embodiments discussed. To the contrary, the discussion of selected embodiments is intended to underscore the breadth and scope of the present invention, without limitation. As should be apparent to those skilled in the art, variations and equivalents of the described embodiments may be employed without departing from the scope of the present invention.

In addition, aspects of the present invention will be discussed in connection with specific materials and/or components. Those materials and/or components are not intended to limit the scope of the present invention. As should be apparent to those skilled in the art, alternative materials and/or components may be employed without departing from the scope of the present invention.

In the illustrations appended hereto, for convenience and brevity, the same reference numbers are used to refer to like features in the various embodiments of the present invention. The use of the same reference numbers for the same or similar structures and features is not intended to convey that each element with the same reference number is identical to all other elements with the same reference number. To the contrary, the elements may vary from one embodiment to another without departing from the scope of the present invention.

Before discussing the details of specific embodiments of the present invention, a brief overview of the present invention is provided.

The present invention provides an improved monitor for a fiber laser system, referred to herein as a fiber laser system monitor.

Traditional fiber laser system monitors are known to incorporate a photodiode that is configured to monitor the intensity of light generated by the fiber laser. If the photodiode detects too much light, this can indicate a problem with the fiber laser requiring correction. Typically, the photodiode is configured to detect a problem so that repairs may be made before the failure leads to significant or irreparable damage to the fiber laser and any associated componentry.

There are, however, instances where, if the failure of a fiber laser is not detected early or quickly enough, it may not be possible to repair damage done to the fiber laser and associated componentry. Since fiber lasers are expensive, there has developed a need for improved failure detection in connection with fiber lasers.

It has been discovered that, because prior art systems rely on the photodiode to detect light emitted from the fiber laser, it may not be possible to detect a fiber laser problem in instances, for example, when the photodiode degrades, becomes damaged, becomes disconnected, or becomes occluded (partially or totally). A photodiode may become occluded if it becomes covered with soot, debris, dirt, oxides, or other material(s). Where the operation of the photodiode is degraded, the system receives a signal from the photodiode that may be within acceptable operating parameters, even though a problem may have occurred. Where the operation of the photodiode is completely compromised, the system will not receive any signal, which also may result in the system determining that a problem does not exist.

To improve upon the prior art and provide more robust detection reliability, the present invention provides for the construction of a fiber laser system monitor that incorporates, among other features, one or more light emitters, which are also referred to as “stimuli.” The light emitters are configured to emit reference light as a stimulus that is detected by the photodiode.

If the photodiode generates a signal that deviates from a signal consistent with the known parameters of the reference light, it becomes possible to determine if there is a failure (partial or otherwise) of the photodiode.

For the present invention, the light emitters are contemplated to cooperate with a controller to create a safety-compliant interlock system for the fiber laser. The controller may include one or more processors that execute software that implements the interlock system for the fiber laser.

In one contemplated configuration, the light emitters are contemplated to generate light in a pulsed manner. If so, the photodiode will generate signals consistent with the pulsed, input stimuli. The signals are received by the controller/processor to assess if the signals indicate acceptable operating parameters for the fiber laser system. If not, appropriate action may be taken. For example, the controller may be configured to transmit a shutdown signal to the fiber laser.

Still further, the light emitters are contemplated to generate light periodically to monitor the operation of the fiber laser.

Various contemplated configurations of the fiber laser system monitor are now discussed in connection with the figures appended hereto.

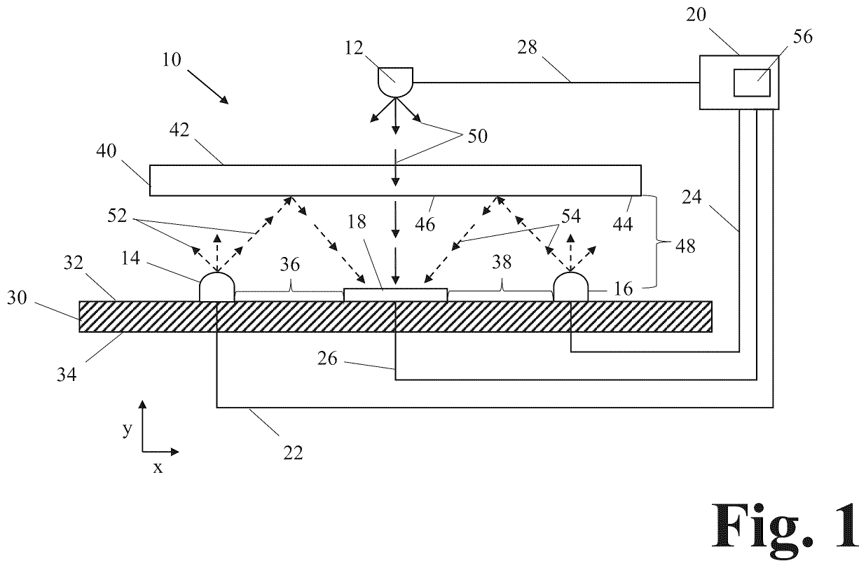

FIG. 1 is a graphical, cross-sectional side view of a fiber laser system monitor according to a first embodiment of the present invention.

The fiber laser system monitor 10 includes a fiber laser 12, a first light emitter 14, a second light emitter 16, a photodiode 18, and a controller 20. The first light emitter 14 is connected to the controller 20 via a first communication link 22. The second light emitter 16 is connected to the controller 20 via a second communication link 24. The photodiode 18 is connected to the controller 20 through a third communication link 26. The fiber laser 12 is connected to the controller by a fourth communication link 28.

In the embodiment illustrated in FIG. 1, the photodiode 18 is disposed on a substrate 30, specifically on a substrate top surface 32. The first light emitter 14 also is disposed on the substrate top surface 32. In addition, the second light emitter 16 is disposed on the substrate top surface 32.

The substrate 30 also has a substrate bottom surface 34.

While not limiting of the present invention, the photodiode 18 is disposed at or near to a center point of the substrate top surface 32. As illustrated, the first light emitter 14 is disposed a first predetermined distance 36 from the photodiode 18. The second light emitter 16 is disposed a second predetermined distance 38 from the photodiode 18.

A reflector 40 is disposed between the fiber laser 12 and the photodiode 18. The reflector 40 has a reflector top surface 42 and a reflector bottom surface 44. The reflector bottom surface 44 is disposed a third predetermined distance 48 from the photodiode 18.

The reflector bottom surface 44 includes a reflective coating 46 thereon. As such, the reflector bottom surface 44 is provided with reflective properties.

As also illustrated in FIG. 1, fiber laser light 50 is emitted from the fiber laser 12. The fiber laser light 50 passes through the reflector 40 and is received by the photodiode 18. First emitted light 52 from the first light emitter 14 reflects from the reflective coating 46 on the reflector bottom side 44. As a result, the first emitted light 52 also is received by the photodiode 18. Similarly, second emitted light 54 from the second light emitter 16 reflects from the reflector bottom surface 44 so that the second emitted light 54 also is received by the photodiode 18.

As should be apparent from the foregoing, the reflective coating 46 possesses both light reflective properties and light transmissive properties in this embodiment. Having both properties, the reflective coating 46 permits the fiber laser light 50 to pass therethrough. In addition, the reflective coating 46 reflects the first emitted light 52 from the first light emitter 14 and the second emitted light 54 from the second light emitter 16. The first emitted light 52 and the second emitted light 54 are received by the photodiode 18 together with the fiber laser light 50.

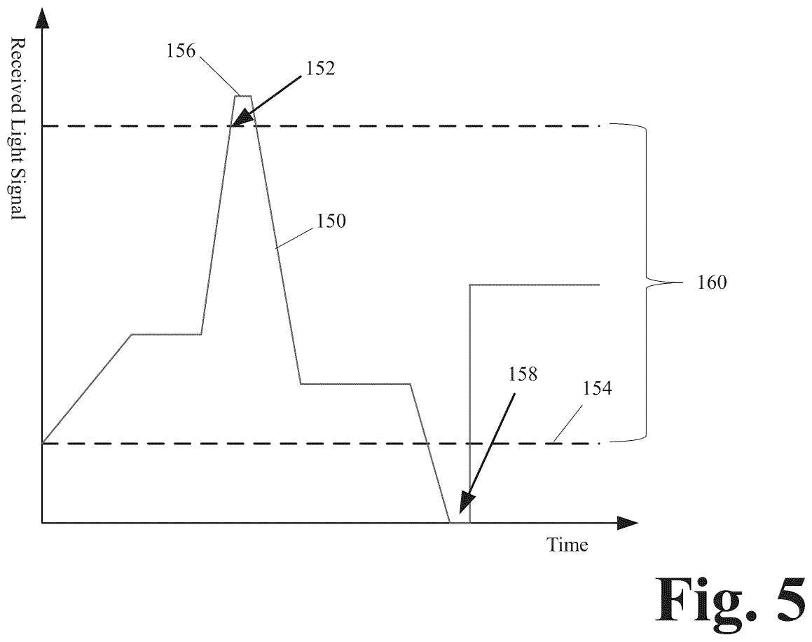

Light received by the photodiode 18 results in the creation of a received light signal 150, illustrated in FIG. 5. The received light signal 150 is provided to the controller 20 via the third communication link 26.

Operational signals are provided by the controller 20 to the fiber laser 12 via the third communication link 28, causing the fiber laser 12 to generate fiber laser light 50. The fiber laser light 50 is emitted from the fiber laser 12, passes through the reflector 40, and is received by the photodiode 18. The photodiode 18 then generates the received light signal 150.

Also, operational signals are provided by the controller 20 to the first light emitter 14 via the first communication link 22, causing the first light emitter 14 to generate the first emitted light 52. The first emitted light 52 is reflected from the reflector 40 and is received by the photodiode 18. The photodiode 18 generates the received light signal 150 therefrom.

In addition, operational signals are provided by the controller 20 to the second light emitter 16 via the second communication link 24, causing the second light emitter 16 to generate the second emitted light 54. The second emitted light 54 reflects from the reflector 40 and is received by the photodiode 18. As with the fiber laser light 50 and the first emitted light 52, the photodiode 18 generates the received light signal 150 in response to receipt of the second emitted light 54.

As discussed in greater detail below, the received light signal 150 that is sent from the photodiode 18 to the controller 20 is used by the controller 20 to control the operation of the fiber laser 12. In particular, if the received light signal 150 is above an upper threshold or below a lower threshold, the received light signal 150 is considered to be aberrant. The controller 20 may cease operation of the fiber laser 12 if the received light signal 150 is aberrant.

It is contemplated that the controller 20 will include a processor 56 that receives the received light signal 150 and compares the received light signal 150 to a minimum threshold value and a maximum threshold value. As such, the processor 56 is contemplated to act as a window comparator, which is a comparator that assess the magnitude of a signal within a predetermined window, i.e., between upper and lower limits. Here, the window comparator is contemplated to be executed as software by the processor 56 in the controller 20. Alternatively, the window comparator function may be executed entirely by hardware that is configured within the controller 20.

It is noted that the present invention is described in connection with one controller 20. However, the present invention is not limited to a single controller 20. The present invention may include several controllers that cooperate with one another.

Before discussing the operation of the fiber laser system monitor 10 in greater detail, additional details about the various components of the fiber laser system monitor 10 are now provided.

The fiber laser 12 is contemplated to generate fiber laser light 50 in the kW range. This range may fall between 1 kW and 1,000 kW, for example. Fiber laser light 50 having a power in the 1-1,000 kW range typically is used for industrial purposes. For example, the fiber laser light 50 may be used for welding, brazing, and the like.

For purposes of discussion, the intensity of the fiber laser light 50 is referred to in the unit of Watts, which is a convention relied upon by those skilled in the art.

The majority of the fiber laser light 50 typically is directed to a predetermined target area (not shown) where, for example, welding takes place. However, some of the fiber laser light 50 is expected to leak from the fiber laser 12. Leakage of fiber laser light 50 is considered to be normal and acceptable, because no fiber laser 12 is capable of directing 100% of its fiber laser light 50 to a selected target. In other words, some leakage of fiber laser light 50 is expected.

The fiber laser light 50 illustrated in FIG. 1 is contemplated to be of this leaked variety. And, as should be apparent to those skilled in the art, the leaked fiber laser light 50 is contemplated to be of a negligible power/intensity by comparison to the fiber laser light 50 directed to the predetermined target.

For purposes of the present invention, the fiber laser 12 may be constructed in any manner consistent with the level of skill in the art.

For the illustrated example, the fiber laser 12 is contemplated to generate fiber laser light 50 with a power of about 1 kW to about 1,000 kW. However, other ranges for the power of the fiber laser light 50 also are contemplated to fall within the scope of the present invention.

The fiber laser 12 is contemplated to generate fiber laser light 50 with a wavelength of about 1,080 nm. Light with a wavelength of 1,080 nm falls within the infrared portion of the electromagnetic spectrum, which encompasses light with a wavelength of between about 750 nm and 1 mm (1,000,000 nm).

The fiber laser 12 is not limited to the generation of fiber laser light 50 of only a wavelength of 1,080 nm. More broadly, the fiber laser 12 may generate light in other portions of the infrared range. For example, the fiber laser 12 may generate fiber laser light 50 in a range from about 750 nm to about 2,500 nm. Other ranges for the wavelength of the fiber laser light 50 are contemplated to be about 750 nm-2,000 nm, about 750 nm-1,500 nm, about 750 nm-1250 nm, about 800 nm-1,200 nm, about 900 nm-1,150 nm, about 1,000 nm-1,150 nm, and about 1,050-1,150 nm, for example.

In addition, while FIG. 1 illustrates only one fiber laser 12, it is contemplated that the fiber laser system monitor 10 may include more than one fiber laser 12 without departing from the scope of the present invention.

The first light emitter 14 and the second light emitter 16 are contemplated to be light emitting diodes (“LEDs”). The construction of LEDs is within the level of skill in the art and, therefore, further details are not provided here. While contemplated to be LEDs, the first and second light emitters 14, 16, may have any other construction without departing from the scope of the present invention.

In one contemplated embodiment, the wavelength of the light generated by the first light emitter 14 and by the second light emitter 16 is identical to or nearly identical to the wavelength of the fiber laser light 50 emitted by the fiber laser 12. As such, in one contemplated embodiment, the fiber laser 12, the first light emitter 14, and the second light emitter 16 generate light with a wavelength of about 1,080 nm.

While not intending to be limiting of the present invention, like the fiber laser 12, the first and second light emitters 14, 16 may generate light with a wavelength anywhere within the infrared range. For example, the first and second light emitters 14, 16 may generate fiber laser light 50 in a range from about 750 nm to about 2,500 nm. Other ranges for the first and second emitted light 52, 54 is contemplated to be about 750 nm-2,000 nm, about 750 nm-1,500 nm, about 750 nm-1250 nm, about 800 nm-1,200 nm, about 900 nm-1,150 nm, about 1,000 nm-1,150 nm, and about 1,050-1,150 nm, for example.

It is noted that the light emitters 14, 16 also may generate light in the visible part of the electromagnetic spectrum. Specifically, the light emitters 14, 16 may generate visible light in addition to and/or independently of generating light in the infrared portion of the spectrum. Depending on the photodiodes used, it is contemplated, for example, that the wavelength of light generated by the light emitters 14, 16 may be in the visible range as well as in the infrared range. The present invention, therefore, should not be understood to be limited solely to light emitters 14, 16 that generate light only in the infrared portion of the electromagnetic spectrum. To the contrary, the light emitters 14, 16 may generate light in either and/or both of the visible portion of the electromagnetic portion of the spectrum as well as the invisible portion of the electromagnetic spectrum without departing from the scope of the invention.

It is contemplated that the fiber laser system monitor 10 will incorporate two light emitters, as shown. Two light emitters 14, 16 provide system redundancy. This assures that the fiber laser system monitor 10 may operate if one of the two light emitters 14, 16 should fail. In an alternative contemplated construction within the scope of the present invention, the fiber laser system monitor 10 may include more than two light emitters 14, 16.

It is also contemplated that the present invention may be constructed to incorporate only the first light emitter 14. However, as noted above, two or more light emitters 14, 16 are understood to provide increased sensitivity to potential problems. At least for this reason, two or more light emitters 14, 16 are preferred.

The first communication link 22, the second communication link 24, the third communication link 26, and the fourth communication link 28 are contemplated to be wired communication links, as illustrated throughout the various figures of the drawings. In the alternative, one or more of the communication links 22, 24, 26, 28 may be wireless links without departing from the scope of the present invention.

Still further, the first communication link 22, the second communication link 24, the third communication link 26, and the fourth communication link 28 are contemplated to facilitate two-way communication with the controller 20. In other words, information may be transmitted bidirectionally thereby. In alternative constructions, one or more of the first communication link 22, the second communication link 24, the third communication link 26, and the fourth communication link 28 may be unidirectional without departing from the scope of the present invention.

The substrate 30 is contemplated to be a printed circuit board (“PCB”) of the type conventionally known to those skilled in the art. A PCB encompasses, but is not limited to, an electronic circuit having thin strips of a conducting material, such as copper, printed and/or etched onto a flat insulating sheet.

A PCB is contemplated for use as the substrate 30, because a PCB is understood to be configured easily to receive the first light emitter 14, the second light emitter 16, and the photodiode 18 thereon. A PCB also provides a convenient platform for organizing components and distancing components from one another. Moreover, a PCB provides a suitable, planar surface on which to assemble components.

As noted above, the first light emitter 14 is disposed a first predetermined distance 36 from the photodiode 18. Similarly, the second light emitter 16 is disposed a second predetermined distance 38 from the photodiode 18. In the embodiment illustrated in FIG. 1, the first predetermined distance 36 is contemplated to be equal to the second predetermined distance 38. However, the first predetermined distance 36 need not be equal to the second predetermined distance 38. In alternative contemplated embodiments of the present invention, the first predetermined distance 36 may be less than the second predetermined distance 38. Still further, the first predetermined distance 36 may be greater than the second predetermined distance 38 without departing from the scope of the present invention.

The photodiode 18 may be of any type know to those skilled in the art. As discussed above, the photodiode 18 is contemplated to detect light in the infrared region of the electromagnetic spectrum, consistent with the light emissions from the fiber laser 12, the first light emitter 14, and the second light emitter 16. However, the photodiode 18 may be configured to detect a broader spectrum of electromagnetic radiation, as required or as desired.

The construction of the reflector 40 may be made from any of a number of materials that permit infrared radiation to pass therethrough. Examples of infrared transmissive materials include, but are not limited to, germanium glass, barium fluoride, potassium bromide, cesium iodide, potassium chloride, cadmium telluride, sapphire, silicon, calcium fluoride, gallium arsenide, sodium chloride, fused silica, magnesium fluoride, zinc selenide, zinc sulfide, lithium fluoride, Schott glass, infrared plastics, and the like.

As noted above, the reflector 40 is contemplated to include a reflective surface 46. In the illustrated embodiment, the reflective coating 46 is disposed on the bottom surface 44 of the reflector 40. In an alternate embodiment, the reflective coating 46 may be disposed on the top surface 42 of the reflector 40. Still further, it is contemplated that the reflector 40 may incorporate or be made from a material that reflects the emitted light 52, 54. In such a case, the reflector 40 may not include a reflective coating 46.

In another contemplated embodiment, the reflector 40 may be a reflective sheet of material that is not supported by a substrate or backing material.

As discussed above, the reflector 40 is disposed a third predetermined distance 48 from the photodiode 18. It is contemplated that this distance may be equal to the first predetermined distance 36 or to the second predetermined distance 38. In other contemplated embodiments, the third predetermined distance 48 may be greater than or less than either or both of the first predetermined distance 36 and the second predetermined distance 38 without departing from the scope of the present invention.

It is noted that the first predetermined distance 36, the second predetermined distance 38, and the third predetermined distance 48 may be selected to minimize the three distances to assure that the light 50, 52, 54 reaches the photodiode 18. As the distances 36, 38, 48 are increased, there is a greater probability of light scattering that may reduce the amount of light 50, 52, 54 reaching the photodiode 18.

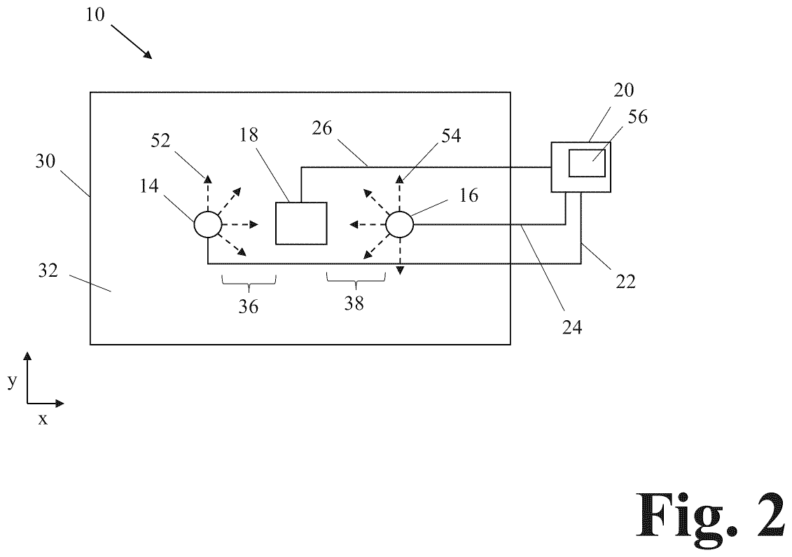

FIG. 2 is a graphical, top view of the fiber laser system monitor 10 illustrated in FIG. 1. In this illustration, one contemplated arrangement of the first light emitter 14, the second light emitter 16, and the photodiode 18 on the substrate 30 is shown. It is noted that this configuration is merely exemplary of the arrangements that are possible without departing from the scope of the present invention.

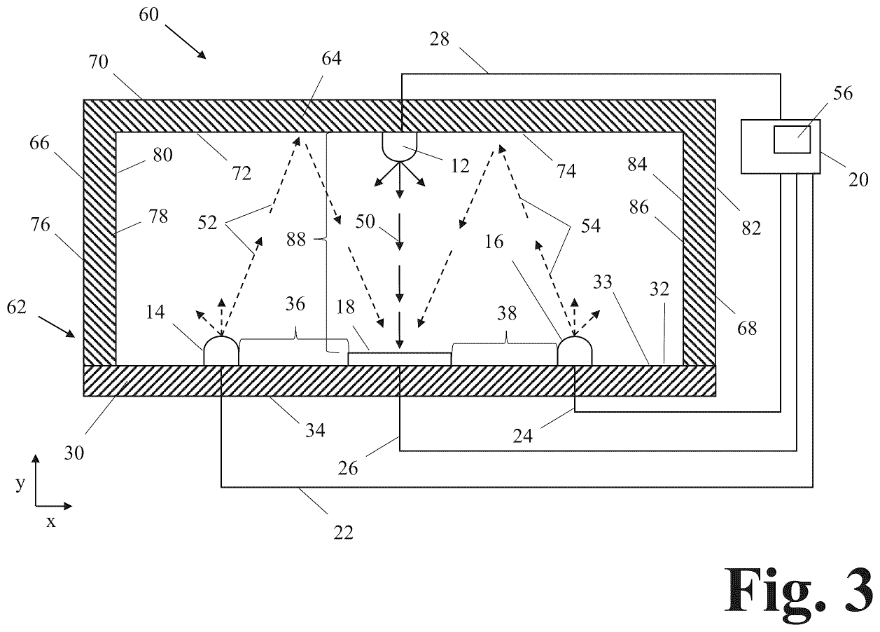

FIG. 3 is a graphical, side view of a second fiber laser system monitor 60 according to the second embodiment of the present invention.

The second fiber laser system monitor 60 is similar to the first fiber laser system monitor 10 in many respects. For example, the second fiber laser system monitor 60 includes a fiber laser 12, a first light emitter 14, a second light emitter 16, a photodiode 18, and a controller 20 in the same configuration as set forth for the first fiber laser system monitor 10 illustrated in FIGS. 1 and 2. In addition, the second fiber laser system monitor 60 includes a first communication link 22, a second communication link 24, a third communication link 26, and a fourth communication link 28 to connect the controller 20 and the processor 56 to the fiber laser 12, the first light emitter 14, the second light emitter 16, and the photodiode 18, in the same configuration as discussed above in connection with the first fiber laser system monitor 10. Still further, the first light emitter 14 is separated from the photodiode 18 by a first predetermined distance 36, and the second light emitter 16 is separated from the photodiode 18 by a second predetermined distance 38, in the same manner as previously described.

The second fiber laser system monitor 60 differs from the first fiber laser system monitor 10 in that the second fiber laser system monitor 60 excludes the reflector 40. In this embodiment, the second fiber laser system monitor 60 includes a housing 62.

In FIG. 3, a top side wall 64, a first side wall 66, and a second side wall 68 are illustrated for the housing 62. The housing 62 is contemplated to have five side walls and define a rectangular, three-dimensional lid or bucket that sits atop the substrate 30.

The top side wall 64 has a top wall exterior surface 70 and a top wall interior surface 72. The top wall interior surface 72 has a top wall reflective coating 74 thereon, making the top wall interior surface a reflector. The first side wall 66 has a first side wall exterior surface 76 and a first side wall interior surface 78. The first side wall interior surface 78 has a first side wall reflective coating 80 thereon, making the first side wall interior surface 78 a reflector. The second side wall 68 has a second side wall exterior surface 82 and a second side wall interior surface 84. The second side wall interior surface 84 has a second side wall reflective coating 88 thereon, making the second side wall interior surface 84 a reflector. As should be apparent, in this embodiment, the entire interior surface of the housing 62 is reflective. However, it is contemplated that only a portion of the interior surface of the housing 62 may be reflective without departing from the scope of the present invention.

As illustrated in FIG. 3, the top side wall interior surface 72 is disposed a fourth predetermined distance 88 away from the photodiode 18.

As should be apparent from FIG. 3, the fiber laser light 50, the first emitted light 52, and the second emitted light 54 are received by the photodiode 18 in much the same way as in the first fiber laser system monitor 10. In this second embodiment, however, the light 50, 52, 54 reflects off of the reflective coatings 74, 80, 86 (also referred to as “reflectors”) that are provided on respective interior wall surfaces 72, 78, 84 of the housing 62.

It is noted that the top substrate surface 32 also may be provided with a reflective coating 33 so that this surface also possesses reflective properties.

In an alternative embodiment, the interior wall surfaces 72, 78, 84 need not be provided with reflective coatings 74, 80, 86. Instead, the interior wall surfaces 72, 78, 84 may possess reflective properties such that reflective coatings 74, 80, 86 are not needed. Whether provided with reflective coatings 74, 80, 86 or polished to present reflective surfaces, the interior wall surfaces 72, 78, 84 are contemplated to be reflectors.

Is this second fiber laser system monitor 60, it is contemplated that the fourth predetermined distance 88 is larger than the first predetermined distance 36 and the second predetermined distance 38. However, it is also contemplated that the fourth predetermined distance 88 may be equal to the first predetermined distance 36 and the second predetermined distance 38. Still further, the fourth predetermined distance 88 may be greater than one or both of the first predetermined distance 36 and the second predetermined distance 38. Moreover, the fourth predetermined distance 88 may be less than one or both of the first predetermined distance 36 and the second predetermined distance 38.

The second fiber laser system monitor 60 is contemplated to operate in the same way as discussed in connection with the first fiber laser system monitor 10.

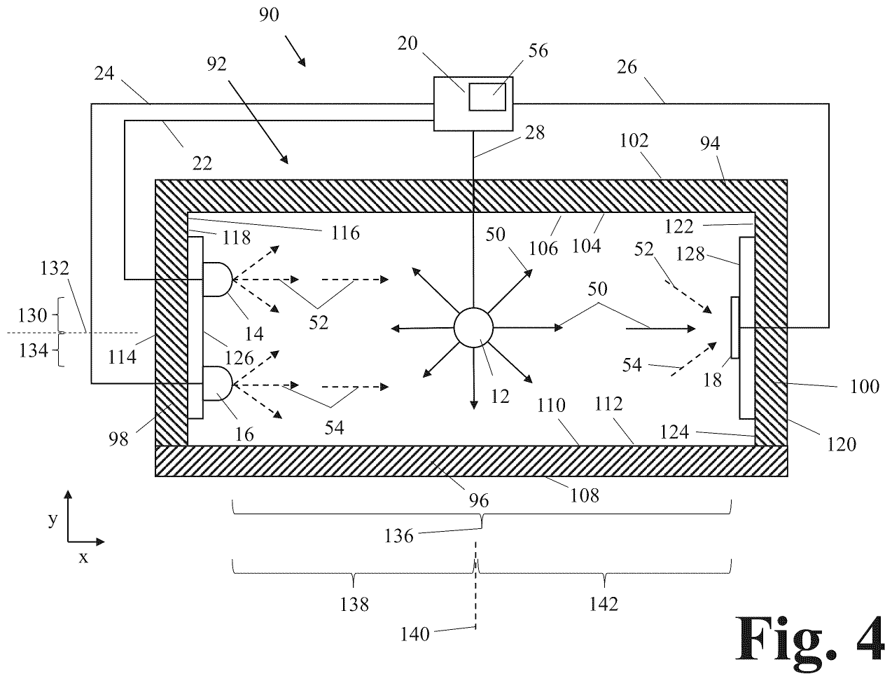

FIG. 4 is a graphical, side view of a third fiber laser monitor 90 according to a third embodiment of the present invention.

The third fiber laser system monitor 90 is similar to the first fiber laser system monitor 10 and to the second fiber laser system monitor 60 in many respects. For example, the third fiber laser system monitor 90 includes a fiber laser 12, a first light emitter 14, a second light emitter 16, a photodiode 18, and a controller 20. In addition, the third fiber laser system monitor 90 includes a first communication link 22, a second communication link 24, a third communication link 26, and a fourth communication link 28 to connect the controller 20 and processor 56 to the fiber laser 12, the first light emitter 14, the second light emitter 16, and the photodiode 18.

The third fiber laser system monitor 90 also includes a housing 92, similar to the housing 62. The housing 92 includes a top side wall 94, a bottom side wall 96, a first side wall 98, and a second side wall 100. The top side wall 94 has a top wall exterior surface 102 and a top wall interior surface 104. The top wall interior surface 104 is provided with a top wall reflective coating 106, so that the top wall interior surface 104 is a reflector. The bottom side wall 96 has a bottom wall exterior surface 108 and a bottom wall interior surface 110. The bottom wall interior surface 110 has a bottom wall reflective coating 112 thereon, so that the bottom wall interior surface 110 is a reflector. The first side wall 98 is defined by a first side wall exterior surface 114 and a first side wall interior surface 116. The first side wall interior surface 116 includes a first side wall reflective coating 118, so that the first side wall interior surface 116 is a reflector. The second side wall 100 includes a second side wall exterior surface 120 and a second side wall interior surface 122 with a second side wall reflective coating 124 thereon, so that the second side wall interior surface 122 is a reflector.

As with the housing 62, the housing 92 is contemplated to be formed as a rectangular, five-walled bucket that sits atop the bottom side wall 96. However, as should be apparent to those skilled in the art, alternative constructions may be employed.

Similarly, as with the housing 62, the housing 92 may be constructed so that the interior wall surfaces 104, 110, 116, 122 are polished to present reflective surfaces, thereby acting as reflectors.

The third fiber laser system monitor 90 differs from the first fiber laser system monitor 10 and the second fiber laser system monitor 60 in several respects. For example, the first light emitter 14 and the second light emitter 16 are disposed on a first substrate 126 disposed on the first side wall interior surface 116. The photodiode 118 is disposed on a second substrate 128 that is disposed on the second side wall interior surface 122. In this embodiment, the light emitters 14, 16 and the photodiode 18 are disposed in a relationship where the components face one another. Moreover, the fiber laser 12 is positioned between the light emitters 14, 16 and the photodiode 18, which configuration differs from the other embodiments described herein.

It is noted that all or part of the surfaces of the sub states 126, 128 may be provided with a reflective coating to provide the surfaces with reflective properties.

As with the fiber laser system monitor 60, the walls 94, 96, 98, 100 are provided with reflective coatings 106, 112, 118, 124. The reflective coatings 106, 112, 118, 124 reflect the first emitted light 52, the second emitted light 54, and the fiber laser light 50 so that the light, 50, 52, 54 may be received by the photodiode 18.

For the fiber laser system monitor 90, the first light emitter 14 is disposed a fifth predetermined distance 130 from a first axis 132, parallel to an x-axis, that transects the fiber laser 12. The second light emitter 16 is disposed a sixth predetermined distance 134 from the first axis 132. Here, the fifth predetermined distance 130 is equal to the sixth predetermined distance 134. However, in alternative contemplated embodiments, the fifth predetermined distance 130 may be greater than or less than the sixth predetermined distance 134 without departing from the scope of the present invention.

As also illustrated, the light emitters 14, 16 are disposed a seventh predetermined distance 136 from the photodiode 18, as measured along the x-axis.

In this embodiment, the light emitters 14, 16 and the photodiode 18 are separated from the fiber laser 12. Specifically, the light emitters 14, 16 are disposed an eighth predetermined distance 138 from a second axis 140, parallel to a y-axis, that transects the fiber laser 12. The photodiode 18 is disposed a ninth predetermined distance 142 from the second axis 140. Here, the eighth predetermined distance 138 is equal to the ninth predetermined distance 142. However, in alternative contemplated embodiments, the eighth predetermined distance 138 may be greater than or less than the ninth predetermined distance 142 without departing from the scope of the present invention.

FIG. 5 is a graph providing a representative output for the photodiode 18 according to the present invention.

Specifically, the graph illustrates one contemplated received light signal 150 that may be generated by the photodiode 18. The graph plots the received light signal 150 as a function of time.

For the instant discussion, it is contemplated that the received light signal 150 is a current I (measured in amperes) that is generated by the photodiode 18 in response to receipt of the fiber laser light 50 emitted by the fiber laser 12, the first emitted light 52 from the first light emitter 14, and/or the second emitted light 54 from the second light emitter 16. The received light signal 150 need not be a current. Instead, the received light signal 150 may be a voltage V or other suitable type of output as required or as desired.

As illustrated in FIG. 5, a predetermined maximum threshold 152 and a predetermined minimum threshold 154 define upper and lower limits for the received light signal 150.

The predetermined maximum threshold 152 indicates if the light received by the photodiode 18 exceeds a maximum limit value. Light that exceeds the predetermined maximum threshold 152 may indicate a failure of the fiber laser 12 and/or one or both of the light emitters 14, 16. For example, if the received light signal 150 is measured as a high value 156, the high value 156 may indicate that the fiber laser 12 has failed in a manner where too much fiber laser light 50 is being emitted. Such a condition might be consistent with a defect in the fiber laser 12. If the photodiode 18 generates a high value 156, the controller 20 may stop the operation of the fiber laser 12. If stopped quickly enough, damage to fiber laser system monitor 10, 60, 90 may be minimized.

The predetermined minimum threshold 154 indicates if the light received by the photodiode 18 falls below a minimum limit value. Light that falls below the predetermined maximum threshold 154 may indicate a failure, for example, of the fiber laser 12 and/or one or both of the light emitters 14, 16. For example, if the received light signal 150 is measured as a low value 158, the low value 158 may indicate that the fiber laser 12 has failed in a manner where too little fiber laser light 50 is being emitted. Such a condition might be consistent with a defect in the fiber laser 12. If the photodiode 18 generates a low value 158, the controller 20 may stop the operation of the fiber laser 12. If stopped quickly enough, damage to fiber laser system monitor 10, 60, 90 may be minimized.

Still further, it is contemplated that the light emitters 14, 16 will be operated when the fiber laser 12 is in an OFF condition. When the fiber laser 12 is OFF, the emitted light 52, 54 received by the photodiode 18 is converted to a received light signal 150 that is compared to the predetermined maximum threshold 152 and the predetermined minimum threshold 154. If the received light signal 150 generated by the photodiode 18 presents a high value 156 or a low value 154, the received light signal 150 may indicate that the photodiode 18 is not operating properly. As a result, the controller 20 may prevent the fiber laser 12 from operating.

In an alternative contemplated embodiment, the emitted light 52, 54 may be varied, during a test procedure, to generate a series of received light signals 150. The received light signals 150 may then be evaluated by the controller 20 to assess the overall health of the fiber laser system containing the fiber laser system monitor 10, 60, 90. If the fiber laser system monitor 10, 60, 90 indicates that the fiber laser 12 should remain in the OFF position, the controller 20 may prevent the fiber laser 20 from being turned ON.

Still further, it is contemplated that periodic checks may be made by the fiber laser system monitor 10, 60, 90 during operation of the fiber laser 12. Here, for example, the light emitters 14, 16 may be pulsed in a particular pattern and with a particular intensity. The patterned emitted light 52, 54 may then be evaluated by the controller 20 to assess the overall health of the fiber laser system.

From the foregoing, it should be apparent that the controller 20 is contemplated to evaluate the emitted light 50, 52, 54 within a window between the predetermined maximum threshold 152 and the predetermined minimum threshold 154. For this reason, the controller operates as a window discriminator, with the window 160 being the difference between the predetermined maximum threshold 152 and the predetermined minimum threshold 154.

One aspect associated with the fiber laser system monitor 10, 60, 90 of the present invention lies in that ability of the device to assess the health of the photodiode 18 before the fiber laser 12 is turned ON. Once the fiber laser 12 is turned ON, several methods may be employed to assess the health of the photodiode 18. It is contemplated that the processor 56 may be enabled to execute one or more algorithms to compare the generated light signal 150 with what is expected for a given operating condition of the fiber laser 12. If implemented as software, the algorithms may be changed, as required or as desired, for a particular fiber laser 12.

In one or more contemplated embodiments, to validate the operational status of the photodiode 18, the light emitters 14, 16 are contemplated to be pulsed at a frequency of 10-100 Hz (10-100 times per second). As noted above, each pulse will cause the photodiode to generate the received light signal 150 that can be evaluated by comparison with the predetermined maximum threshold 152 and the predetermined minimum threshold 154. Here, the operational status of the photodiode 18 may be evaluated during operation of the fiber laser 12. This permits a continuous diagnostic of the photodiode 18 to be executed while the fiber laser 12 is operational.

It is contemplated that the duration of the pulses may be on the order of 100-500 s (microseconds). However, a longer or a shorter pulse duration may be employed without departing from the scope of the present invention.

As discussed hereinabove, the embodiments of the present invention are exemplary only and are not intended to limit the present invention. Features from one embodiment are interchangeable with other embodiments, as should be apparent to those skilled in the art. As such, variations and equivalents of the embodiments described herein are intended to fall within the scope of the claims appended hereto.

What is claimed is:

1. A fiber laser system monitor, comprising:
a fiber laser adapted to generate fiber laser light;
a first light emitter adapted to generate first emitted light;
a photodiode adapted to receive the first emitted light and the fiber laser light and to generate a received light signal responsive thereto; and
a controller connected to the fiber laser, the first light emitter, and the photodiode,
wherein the controller receives the received light signal, and
wherein the controller is configured to determine an acceptable operation for the fiber laser, the first light emitter, and the photodiode by comparing the received light signal with a predetermined maximum threshold and with a predetermined minimum threshold.

2. The fiber laser system monitor according to claim 1, wherein:
the fiber laser is separated from the photodiode by a first predetermined distance.

3. The fiber laser system monitor according to claim 2, further comprising:
a substrate,
wherein the first light emitter and the photodiode are disposed on the substrate.

4. The fiber laser system monitor according to claim 3, wherein:
the first light emitter is separated from the photodiode by a second predetermined distance.

5. The fiber laser system monitor according to claim 1, wherein the first light emitter is a light emitting diode.

6. The fiber laser system monitor according to claim 1, wherein the photodiode detects light within the infrared portion of the electromagnetic spectrum.

7. The fiber laser system monitor according to claim 1, wherein the controller comprises a processor adapted to execute software to determine the acceptable operation for the fiber laser, the first light emitter, and the photodiode by comparing the received light signal with the predetermined maximum threshold and with the predetermined minimum threshold.

8. The fiber laser system monitor according to claim 1, wherein:
if the received light signal exceeds the predetermined maximum threshold, the received light signal is determined to be aberrant,
if the received light signal is below the predetermined minimum threshold, the received light signal is aberrant, and
the controller prohibits operation of the fiber laser when the received light signal is aberrant.

9. The fiber laser system monitor according to claim 3, further comprising:
a reflector,
wherein the reflector is positioned between the substrate and the fiber laser,
wherein the reflector reflects the first light emitter to the photodiode,
wherein the reflector is at least partially transmissive, permitting the fiber laser light to pass therethrough and be received by the photodiode.

10. The fiber laser system monitor according to claim 1, further comprising:
a second light emitter adapted to generate second emitted light,
wherein the received light signal generated by the photodiode also is responsive to the second emitted light.

11. The fiber laser system monitor according to claim 10, further comprising:
a substrate,
wherein the first light emitter, the second light emitter, and the photodiode are disposed on the substrate.

12. The fiber laser system monitor according to claim 11, wherein:
the first light emitter is separated from the photodiode by a third predetermined distance,
the second light emitter is separated from the photodiode by a fourth predetermined distance.

13. The fiber laser system monitor according to claim 12, wherein:
the photodiode is disposed between the first light emitter and the second light emitter.

14. The fiber laser system monitor according to claim 10, wherein:
the first light emitter is a light emitting diode, and
the second light emitter is a light emitting diode.

15. The fiber laser system monitor according to claim 4, wherein the first emitted light and the second emitted light are within the infrared portion of the electromagnetic spectrum.

16. The fiber laser system monitor according to claim 1, further comprising:
a housing encompassing the fiber laser, the first light emitter, and the photodiode,
wherein an interior surface of the housing includes a reflective surface.

17. The fiber laser monitor according to claim 11, further comprising:
a housing encompassing the fiber laser, the first light emitter, and the photodiode,
wherein an interior surface of the housing includes a reflective surface.

18. The fiber laser monitor according to claim 10, further comprising:
a housing encompassing the fiber laser, the first light emitter, and the photodiode,
wherein an interior surface of the housing includes a reflective surface.

19. The fiber laser monitor according to claim 18, further comprising:
a first substrate; and
a second substrate,
wherein the first light emitter and the second light emitter are disposed on the first substrate,
wherein the photodiode is disposed on the second substrate, and
wherein the fiber laser is disposed between the first substrate and the second substrate.

20. The fiber laser monitor according to claim 19, further comprising:
a housing encompassing the fiber laser, the first light emitter, and the photodiode,
wherein an interior surface of the housing includes a reflective surface.
